(19) United States
(12) Patent Application Publication
(10) Pub. No.: US 2025/0081699 A1
(43) Pub. Date: Mar. 6, 2025

(54) SEMICONDUCTOR DEVICE AND FABRICATION METHOD THEREOF

(71) Applicant: EPISTAR CORPORATION, Hsinchu (TW)

(72) Inventors: Chang-Tai HSIAO, Hsinchu (TW); Shih-An LIAO, Hsinchu (TW)

(21) Appl. No.: 18/817,184

(22) Filed: Aug. 27, 2024

(30) Foreign Application Priority Data
Aug. 30, 2023 (TW) 112132890

(51) Int. Cl. H01L 33/62; H01L 33/22; H01L 33/36

(52) U.S. Cl. CPC H10H 20/857; H10H 20/82; H10H 20/83

(57) ABSTRACT

A semiconductor device comprises a first semiconductor stack comprising a first type semiconductor layer and a second type semiconductor layer; a protecting layer located on the semiconductor stack comprising n first openings and m second openings; a first electrode located on the n first openings, comprising a first outer surface and electrically connected to the first type semiconductor layer; a second electrode located on the m second openings, comprising a second outer surface and electrically connected to the second type semiconductor layer; a first conductive bump located on the first electrode and including a first convex top; a second conductive bump located on the second electrode and comprising a second convex top. The first top and the second top substantially have a same horizontal elevation.

This application claims priority to the benefit of TW Patent Application Number 112132890 filed on Aug. 30, 2023 and the entire content of which is hereby incorporated by reference herein its entirety.

### TECHNICAL FIELD

The present disclosure relates to a semiconductor device, and in particular, to an electrical connection structure of the semiconductor device and a fabrication method thereof.

### RELATED TECHNOLOGIES

In the semiconductor manufacturing process, the wiring layers at different horizontal elevations are usually connected through the conductive material filled in the vias of the dielectric layer. Usually, to fill up the conductive material into the vias with varying depths to form a flat surface requires multiple manufacturing steps, which is complex and expensive.

In addition, for the packaging structure of the semiconductor chip, the conductive bumps are usually used to establish electrical connections with external circuits, but the existing manufacturing methods for forming the conductive bumps usually cannot accurately control the height of the conductive bumps. The tops of the plurality of conductive bumps in the semiconductor chip are not coplanar with each other, thereby affecting the production yield of the semiconductor chip.

### CONTENTS OF DISCLOSURE

Therefore, the present disclosure provides a method for accurately controlling the size of an electrical connection structure in a semiconductor device, for example, a method that can accurately control the height of a conductive bump in a semiconductor device, and provides a semiconductor device fabricated thereof.

A semiconductor device is provided according to an embodiment of the present disclosure, including a semiconductor stack which includes a first type semiconductor layer and a second type semiconductor layer; a protecting layer which is located on the semiconductor stack and has n first openings and m second openings; a first electrode which is located on the n first openings and has a first outer surface, and is electrically connected to the first type semiconductor layer; a second electrode which is located on the m second openings and has a second outer surface, and is electrically connected to the second type semiconductor layer; a first conductive bump which is located on the first electrode and has a first top with a convex shaped outer contour; and a second conductive bump is located on the second electrode and has a second top with a convex shaped outer contour; wherein, in a cross-sectional view, the first conductive bump is connected to the first electrode through a contacting surface with a first horizontal width, the second conductive bump is connected to the second electrode through a contacting surface with a second horizontal width, and a ratio of the first horizontal width to the second horizontal width is between 0.8-1.2; wherein the first top and the second top substantially have a same horizontal elevation.

### BRIEF DESCRIPTION OF THE DRAWINGS

To make the following easier to understand, the present disclosure can be read with reference to the accompanying drawings and their detailed written description simultaneously. This disclosure describes the specific embodiments in detail through the specific embodiments and combined with the corresponding drawings, and illustrates the working principles of the specific embodiments of the present disclosure. Additionally, features in the drawings may not be drawn to actual scale for the sake of clarity and therefore the size of some features in the drawings may be intentionally exaggerated or reduced.

FIG. 1A is a perspective view of a semiconductor device according to an embodiment of the present disclosure.

FIG. 1B is a cross-sectional view along line A-A′ of the semiconductor device in FIG. 1A.

FIG. 2A is a perspective view of a semiconductor device according to an embodiment of the present disclosure.

FIG. 2B is a cross-sectional view along line B-B′ of the semiconductor device in FIG. 2A.

FIG. 3A is a cross-sectional view of a semiconductor device according to another embodiment of the present disclosure.

FIG. 3B is a cross-sectional view of a semiconductor device according to another embodiment of the present disclosure.

FIG. 4 is a cross-sectional view of a semiconductor device according to another embodiment of the present disclosure.

FIGS. 5A-5D illustrate a manufacturing process of a semiconductor device in accordance with an embodiment of the present disclosure.

### EMBODIMENTS

The present disclosure provides many different embodiments that can be used to implement different features of the disclosure. To simplify illustration, examples of specific elements and arrangements are also described in this disclosure. These examples are provided for illustrative purposes only and are not intended to be limiting. The disclosure may repeat symbols and/or characters of components in different embodiments or examples. This repetition is for simplicity and clarity, rather than to represent the relationship between the different embodiments and/or examples discussed.

In addition, for convenience of description, spatially relative terms such as “below”, “under”, “lower”, “above”, “upper”, “on”, “top”, “bottom” and the like may be used herein to describe relationship of one component or feature to another (or other) component or feature as shown in the figures. Spatially relative terms are intended to comprise different orientations of the component in use or operation in addition to the orientations shown in the figures. The component may be otherwise oriented (rotated 90 degrees or in other orientations) and the spatially relative descriptions used herein may be interpreted accordingly.

Although this disclosure uses terms such as first, second, or third to describe devices, elements, components, regions, layers, and/or sections, it should be understood that these devices, elements, components, regions, layers, and/or or sections shall not be limited by these terms. These terms are only used to distinguish one device, element, component, region, layer and/or section from another device, element, component, region, layer and/or section and do not imply or represent any ordinal. These terms do not imply the order of arrangement of one component relative to another component, or the order of manufacturing processes. Thus, a first device, element, component, region, layer and/or section discussed below could be termed a second device, element, component, region, layer and/or section without departing from the scope of embodiments of the disclosure.

In the present disclosure, the terms “about”, “approximately” and “substantially” typically mean +/−20% of the stated value, more typically +/−10% of the stated value, more typically +/−5% of the stated value, more typically +/−3% of the stated value, more typically +/−2% of the stated value, more typically +/−1% of the stated value and even more typically +/−0.5% of the stated value. It should be noted that the stated value of the present disclosure is an approximate value. That is when there is no specific description of the terms “about”, “approximately” and “substantially”, the stated value includes the meaning of “about”, “approximately” or “substantially”.

The terms “coupling” and “electrical connection” mentioned in this disclosure include any direct and indirect electrical connection. For example, if a first component is coupled to a second component, that means the first component can be directly electrically connected to the second component, or indirectly electrically connected to the second component through other devices or connections.

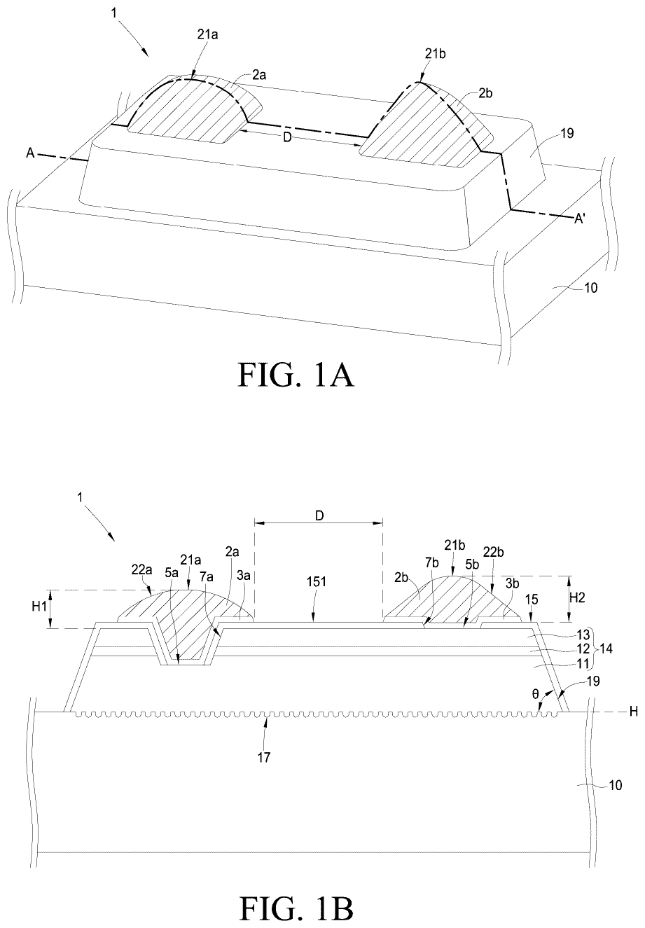

FIG. 1A is a perspective view of a semiconductor device 1 according to an embodiment of the present disclosure, FIG. 1B is a cross-sectional view along line A-A′ of the semiconductor device 1 in FIG. 1A. The semiconductor device 1 can be a light-emitting diode (LED), laser diode (LD), or a transistor. The semiconductor device 1 has a first electrode 3a and a second electrode 3b on a side away from the substrate 10. A first conductive bump 2a and a second conductive bump 2b are directly provided on the first electrode 3a and the second electrode 3b respectively. The upper surfaces of the first conductive bump 2a and the second conductive bump 2b are convex arc-shaped, and are not parallel to the upper surfaces of the first electrode 3a and the second electrode 3b.

The substrate 10 can be a growth substrate for the semiconductor device 1, or a carrier used to replace the growth substrate to support the semiconductor device 1. The material of the substrate 10 includes but is not limited to germanium (Ge), gallium arsenide (GaAs), indium phosphide (InP), sapphire, silicon carbide (SiC), silicon (Si), lithium aluminate (LiAlO₂), zinc oxide (ZnO), gallium nitride (GaN), aluminum nitride (AlN), metal, glass, thermal release tape, photolytic adhesive film (UV release tape), chemical release tape, heat-resistant tape, blue tape, or tape with a dynamic release layer (DRL).

The material of the electrode includes a metal, such as: gold (Au), silver (Ag), copper (Cu), chromium (Cr), aluminum (Al), platinum (Pt), nickel (Ni), titanium (Ti), or an alloy including the above materials, or laminated combinations including the above materials. The material of the conductive bump includes a metal with a lower melting point or an alloy with a lower liquidus melting point, such as a melting point or liquidus melting point lower than 210° C., or for example, the material of the conductive bump includes bismuth (Bi), tin (Sn), indium (In), or their alloys. In one embodiment, the melting point of the metal or the liquidus melting point of the alloy is below 170° C. The material of the alloy includes tin-indium alloy or tin-bismuth alloy.

The maximum length of the semiconductor device 1 is 100 μm or less, or 50 μm or less. For example, the length of the semiconductor device 1 is approximately 40 μm and the width of the semiconductor device 1 is approximately 20 μm. The first conductive bump 2a and the second conductive bump 2b have opposite polarities (positive polarity and negative polarity), and the minimum horizontal distance D between the two bumps 2a, 2b is less than 40 μm. For example, the maximum length of the semiconductor device 1 is approximately 40 μm, and D is approximately 15 μm. The first conductive bump 2a and the second conductive bump 2b cover the electrode (the first electrode 3a and the second electrode 3b as shown in FIG. 1B) completely and has a first top 21a and a second top 21b with a convex arc-shaped outer contour respectively. As shown in FIG. 1A, the first top 21a and the second top 21b are approximately located at a geometric center of the first conductive bump 2a and the second conductive bump 2b and/or the first electrode 3a and the second electrode 3b.

In one embodiment, the semiconductor device 1 is, for example, a LED. The semiconductor device 1 (LED) is provided on a substrate 10 and includes a semiconductor stack 14, a protecting layer 15, a first electrode 3a, a second electrode 3b, a first conductive bump 2a, a second conductive bump 2b, and a lower surface 17. The outermost side surface 19 of the semiconductor stack 14 is an inclined surface, and an included angle θ formed between the outermost side surface 19 and a horizontal extension line H of the lower surface 17 is greater than 70 degrees but less than 85 degrees. The semiconductor stack 14 includes a first type semiconductor layer 11, an active layer 12, and a second type semiconductor layer 13. The first type semiconductor layer 11 and the second type semiconductor layer 13 can provide electrons and holes respectively, and the electrons and holes are recombined in the active layer 12 to emit light. In another embodiment, the included angle between the outermost side surface 19 of the semiconductor stack 14 and the horizontal extension line H of the lower surface 17 is equal to or close to 90 degrees (not shown). The included angle can be adjusted by performing different types of etching processes on the outermost side surface 18 of the semiconductor stack 14 or by adjusting parameters of the etching process.

In one embodiment, the semiconductor device 1 is, for example, a LED, the first type semiconductor layer 11, the active layer 12, and the second type semiconductor layer 13 include III-V group semiconductor materials, such as AlₓIn_{y}Ga_{(1-x-y)}N or AlₓIn_{y}Ga_{(1-x-y)}P, wherein 0≤x, y≤1; (x+y)≤1. Depending on the material of the active layer 12, the semiconductor device 1 (LED) can emit red light with a peak between 610 nm and 650 nm, green light with a peak between 530 nm and 570 nm, cyan light with a peak between 500 nm and 485 nm, blue light with a peak between 450 nm and 490 nm, violet light with a peak between 400 nm and 450 nm, or ultraviolet light with a peak between 280 nm and 400 nm. The maximum thickness of the semiconductor stack 14 is approximately equal to or less than 10 μm. In one embodiment, the lower surface 17 of the first type semiconductor layer 11 is in contact with the substrate 10 and is a rough surface with regular or irregular texture, and a portion of the substrate 10 that is not in contact with the lower surface 17 is a flat surface. In another embodiment, the lower surface 17 of the first type semiconductor layer 11 is a substantially flat surface macroscopically (not shown). In another embodiment, the substrate 10 is a growth substrate for epitaxially growing the semiconductor stack 14, and the entire upper surface of the substrate 10 facing the semiconductor stack 14 is a rough surface with regular or irregular texture (not shown). For example, the substrate 10 is a patterned sapphire substrate (PSS).

Referring to FIG. 1B, the semiconductor device 1 is placed on the substrate 10 and includes the semiconductor stack 14, the protecting layer 15, the first electrode 3a, the second electrode 3b, the first conductive bump 2a, and the second conductive bump 2b. The semiconductor stack 14 has a first opening 5a for exposing a portion of the first type semiconductor layer 11 covered by the active layer 12 and the second type semiconductor layer 13, wherein the first opening 5a has a first inner wall 7a. In addition, the semiconductor stack 14 also has a second opening 5b for exposing a portion of the second type semiconductor layer 13, wherein the second opening 5b has a second inner wall 7b. The protecting layer 15 covers a part of the upper surface of the second type semiconductor layer 13, the sidewalls of the first type semiconductor layer 11, the active layer 12, and the second type semiconductor layer 13, and has an outermost upper surface 151. The lower portion of the protecting layer 15 is in direct contact with the substrate 10 (as shown in FIG. 1B) or not (not shown). The first electrode 3a has a portion located in the first opening 5a and electrically connected to the exposed portion of the first type semiconductor layer 11, and has another portion formed on the protecting layer 15 and covering a portion of the protecting layer 15 around the first opening 5a. The second electrode 3b has a portion located in the second opening 5b and electrically connected to the exposed portion of the second type semiconductor layer 13, and has another portion formed on the protecting layer 15 and covering a portion of the protecting layer 15 around the second opening 5b.

The protecting layer 15 can be a single-layer structure or multi-layers structure and has electrical insulation properties. The material of the single-layer structure includes oxide, nitride, or polymer. The oxide includes aluminum oxide (Al₂O₃), silicon dioxide (SiO₂), titanium dioxide (TiO₂), tantalum pentoxide (Ta₂O₅) or aluminum oxide (AlOₓ). The nitride includes aluminum nitride (AlN), silicon nitride (SiNₓ). The polymer includes polyimide or benzocyclobutane (BCB). The material of the multi-layers structure includes aluminum oxide (Al₂O₃), silicon dioxide (SiO₂), titanium dioxide (TiO₂), niobium pentoxide (Nb₂O₅), silicon nitride (SiNₓ), or a combination of the above materials. The multi-layers structure can also be a distributed Bragg reflector (DBR).

Referring to FIG. 1B, the first conductive bump 2a is formed on the first electrode 3a and filled in the first opening 5a, wherein the outermost surface 22a of the first conductive bump 2a is a smooth convex arc-shaped surface macroscopically. The first conductive bump 2a has a first top 21a, and the first top 21a is the farthest area of the first conductive bump 2a from the substrate 10. The second conductive bump 2b is formed on the second electrode 3b and filled in the second opening 5b, wherein the outermost surface 22b of the second conductive bump 2b is a smooth convex arc-shaped surface macroscopically. The second conductive bump 2b has a second top 21b, and the second top 21b is the farthest area of the second conductive bump 2b from the substrate 10.

In practice, the bottom surfaces of the first conductive bump 2a and the second conductive bump 2b are usually conformally formed on the first electrode 3a and the second electrode 3b, respectively. If the first conductive bump 2a and the second conductive bump 2b are manufactured in the same step, the first electrode 3a and the second electrode 3b usually have different elevations, causing the first top 21a and the second top 21b are generally not at the same elevation. To solve the above problem, the first conductive bump 2a and the second conductive bump 2b are formed in different steps with appropriate material amounts and process conditions, so that the top 21a of the first conductive bump 2a and the top 21b of the second conductive bump 2b are approximately at the same elevation. For example, the ratio of the height H1 to the height H2 is between 0.8 and 1.2.

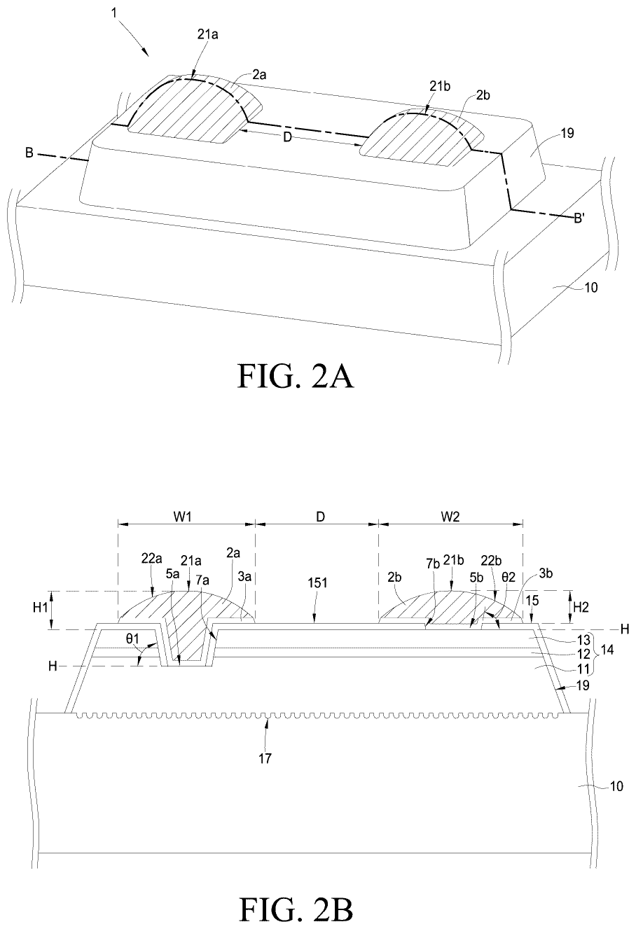

FIG. 2A is a perspective view of a semiconductor device 2 according to an embodiment of the present disclosure. FIG. 2B is a cross-sectional view along line B-B′ of the semiconductor device 1 in FIG. 2A. In order to enable the semiconductor device 2 to be stably fixed on the conductive circuit of the circuit substrate or display panel through the conductive bumps, in one embodiment, in the semiconductor device 2 as shown in FIG. 2B, the outermost surface 22a of the first conductive bump 2a is a smooth convex arc-shaped surface macroscopically, and the outermost surface 22b of the second conductive bump 2b is a smooth convex arc-shaped surface macroscopically, wherein the first top 21a and the second top 21b of the second conductive bump 2b are substantially at the same elevation. The first inner side wall 7a of the first opening 5a has a first slope, and the second inner side wall 7b of the second opening 5b has a second slope, and the first slope and the second slope are different. In one embodiment, the first slope is greater than the second slope. That is to say, a first included angle θ1 is formed between the first inner wall 7a of the first opening 5a and the horizontal extension line H of the bottom surface, a second included angle θ2 is formed between the second inner wall 7b of the second opening 5b and the horizontal extension line H of the bottom surface, and θ1 is greater than θ2. The greater the slope of the inner wall, the smaller the volume of the opening. Therefore, when the same volume of material is filled to form a conductive bump, on the premise that the material does not collapse, the greater the slope of the inner wall of the opening, the higher the conductive bump. Thus, the height of the conductive bump can be adjusted so that the first top 21a of the first conductive bump 2a and the second top 21b of the second conductive bump 2b can be substantially located at the same elevation, that is, the height H1 is approximately equal to the height H2. The manufacturing process of the conductive bumps will be described in the following paragraphs.

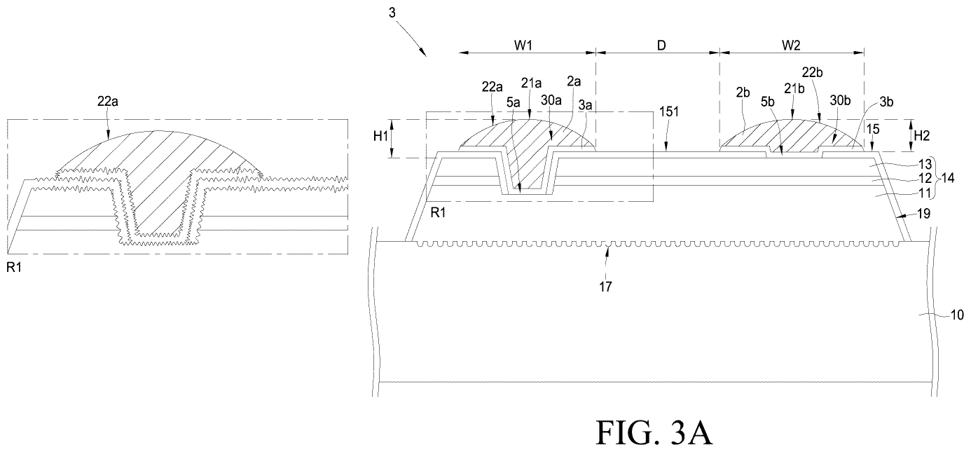

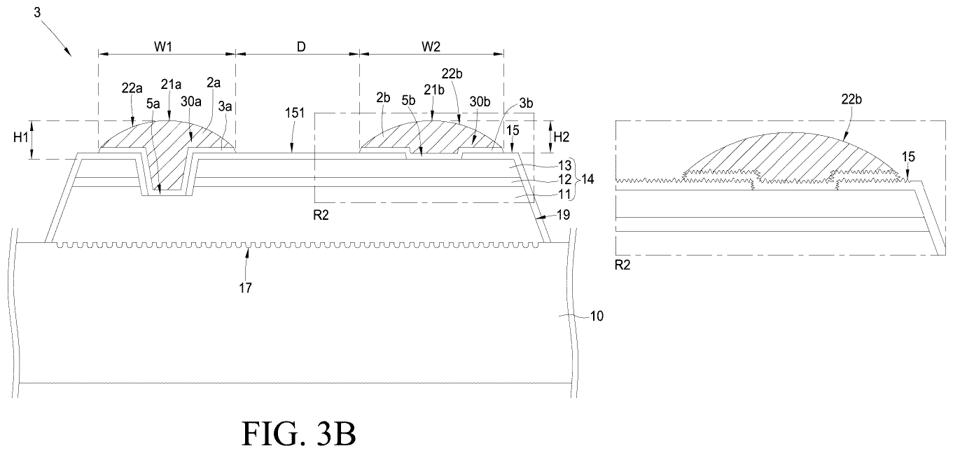

FIGS. 3A and 3B are respectively cross-sectional views of a semiconductor device 3 according to another embodiment of the present disclosure. In the semiconductor device 3, the outermost surface 22a of the first conductive bump 2a is a smooth convex arc-shaped surface macroscopically, and the outermost surface 22b of the second conductive bump 2b is a smooth convex arc-shaped surface macroscopically. In order to enable the semiconductor device 3 to be stably fixed on the conductive circuit of the circuit substrate or display panel through the conductive bumps, the first conductive bump 2a and the second conductive bump 2b at the same elevation (the ratio of the height H1 to the height H2 is between 0.9 and 1.1), for example, the projected areas of the two on the outermost upper surface 151 of the protective layer 15 are similar. As shown in FIG. 3A, the first conductive bump 2a has a first (maximum) horizontal width W1, and the second conductive bump 2b has a second (maximum) horizontal width W2. In one embodiment, the first (maximum) horizontal width W1 and the second (maximum) horizontal width W2 are equal to or similar to each other. For example, the ratio of the first (maximum) horizontal width W1 to the second (maximum) horizontal width W2 is between 0.8 and 1.2.

As shown in FIG. 3A, in one embodiment, the structure directly below the first conductive bump 2a, such as the upper surface of the first electrode 3a (directly in contact with the first conductive bump 2a) is a rough surface. In one embodiment, to form a rough surface on the upper surface of the first electrode 3a (the place in direct contact with the conductive bump 2a), the upper surface of the first electrode 3a can be roughened through an etching process. In another embodiment, a portion of the upper surface of the first type semiconductor layer 11 and the outermost upper surface 151 of the protective layer 15 both under and in direct contact with the first electrode 3a can also be selectively roughened through an etching process. That is to say, when the surface of the structure (portion of the first type semiconductor layer 11 and the protecting layer 15) directly below and in contact with the first electrode 3a is a rough surface, the first electrode 3 can be formed as a layer having a conformal roughness structure along the underlying rough surface. Therefore, the first electrode 3a has a rough upper surface. The detailed structure can be referred from the enlarged view of a partial region R1 in the left half of FIG. 3A.

In the manufacturing process of the conductive bumps, the raw materials of the conductive bumps are first melted into a liquid state, which has different surface tensions when in contact with surfaces of different roughness. Therefore, the contacting surfaces with different roughnesses can result in different contact angles between the raw material of the conductive bump and the contacting surface, thereby changing the curvature radius and/or the height (or the horizontal elevation) of the conductive bump finally formed. In general, the greater the roughness of the contacting surface, the greater the cohesion of the raw material of the conductive bump, causing the smaller the curvature radius of the formed conductive bump. Accordingly, by fine-tuning the surface roughness of the structure under the raw material of the first conductive bump 2a and the second conductive bump 2b, the height (or elevation) of the first conductive bump 2a and the second conductive bump 2b finally formed can be controlled, so as to form the first top 21a and the second top 21b having the same elevation.

In FIG. 3A, a contacting surface under the first conductive bump 2a (the first outer surface 30a of the first electrode 3a) has a greater roughness than a contacting surface under the second conductive bump 2b (the second outer surface 30b of the second electrode 3b), so a curvature radius of the first conductive bump 2a is smaller than a curvature radius of the second conductive bump 2b. As shown in the enlarged view of a region R2 in FIG. 3B, the contacting surface under the second conductive bump 2b (the second outer surface 30b of the second electrode 3b) has a greater roughness than the contacting surface under the first conductive bump 2a (the first outer surface 30a of the first electrode 3a), so the curvature radius of the first conductive bump 2a is greater than the curvature radius of the second conductive bump 2b. As mentioned above, a surface roughening process can be performed by etching the surface of the semiconductor stack and then providing the protecting layer and the electrode both stacked thereon to have the conformally roughened surfaces, or only by etching and roughening the outer surface of the electrode. The present disclosure is not limited thereto.

As shown in the enlarged views of FIGS. 3A and 3B, an exposed portion of the outermost upper surface 151 of the protective layer 15 around the first electrode 3a or the second electrode 3b can also be a rough surface. By this design, even if the raw material of the conductive bump melts into a liquid state and then overflows to the rough outermost upper surface 151 of the protecting layer 15, the surface tension of the contacting surface can be changed by the surface roughness of the outermost upper surface 151 during the manufacturing process, so as to adjust the curvature radius of the conductive bump subsequently formed.

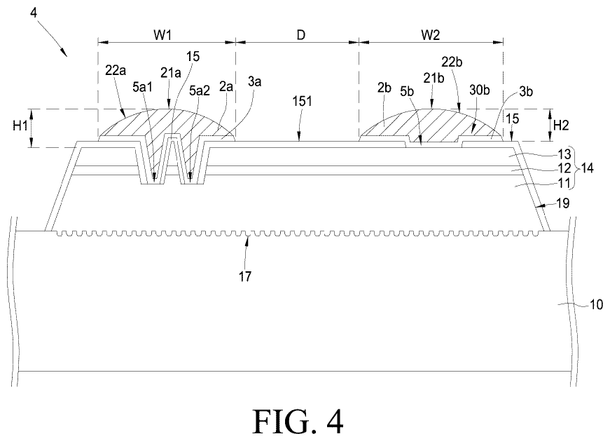

FIG. 4 is a cross-sectional view of a semiconductor device 4 according to another embodiment of the present disclosure. In the semiconductor device 4, the outermost surface 22a of the first conductive bump 2a is a smooth convex arc-shaped surface macroscopically, and the outermost surface 22b of the second conductive bump 2b is a smooth convex arc-shaped surface macroscopically. Furthermore, in order to enable the semiconductor device 4 to be stably fixed on the conductive circuit of the circuit substrate or display panel through the conductive bumps, the first conductive bumps 2a and the second conductive bumps 2b have similar projected areas at the same horizontal elevation (the ratio of the height H1 to the height H2 is between 0.9 and 1.1). As shown in FIG. 4, the first conductive bump 2a has a first (maximum) horizontal width W1, and the second conductive bump 2b has a second (maximum) horizontal width W2. In one embodiment, the first (maximum) horizontal width W1 is equal to or similar to the second (maximum) horizontal width W2. For example, the ratio of the first (maximum) horizontal width W1 and the second (maximum) horizontal width W2 is between 0.8 and 1.2.

As shown in FIG. 4, in one embodiment, the protecting layer 15 has n first openings under the first conductive bumps 2a. When n=2, there are a first first opening 5a1 and a second first opening 5a2 respectively. The first electrode 3a is conformally disposed in the two first openings 5al and 5a2 and electrically connected to the first type semiconductor layer 11; the protecting layer 15 has m second openings 5b under the second conductive bump 2b, wherein m=1. The second electrode 3b is conformally disposed in the second opening 5b and electrically connected to the second type semiconductor layer 13. In the above configuration, the numbers of n and m are examples only. The total capacity of the openings can be controlled by appropriately adjusting the number of openings under the conductive bumps. Therefore, when similar volumes of materials are used to form the conductive bumps, the first top 21a and the second top 21b of the conductive bumps in subsequently formed can be controlled to be at the same elevation (the ratio of the height H1 to the height H2 is between 0.9 and 1.1) by adjusting the height of the conductive bumps. In addition, the ratio of the first opening to the second opening between in the cross-sectional view and the top view may be different according to the capture position of the cross-sectional view and the arrangement pattern of the openings. In one embodiment, when the conductive bumps are ignored, the number of n first openings and m second openings may be the same or different in the top view of the semiconductor device 4. If n and/or m are greater than or equal to a specific number, the overall shape presented by the n first openings and/or the m second openings can be an irregular shape or a regular shape, wherein the regular shape is, for example, a circle, a rectangle, a triangle, or other polygon. If n and/or m is greater than or equal to 3, the distance between two adjacent openings can be a constant value or a variable value.

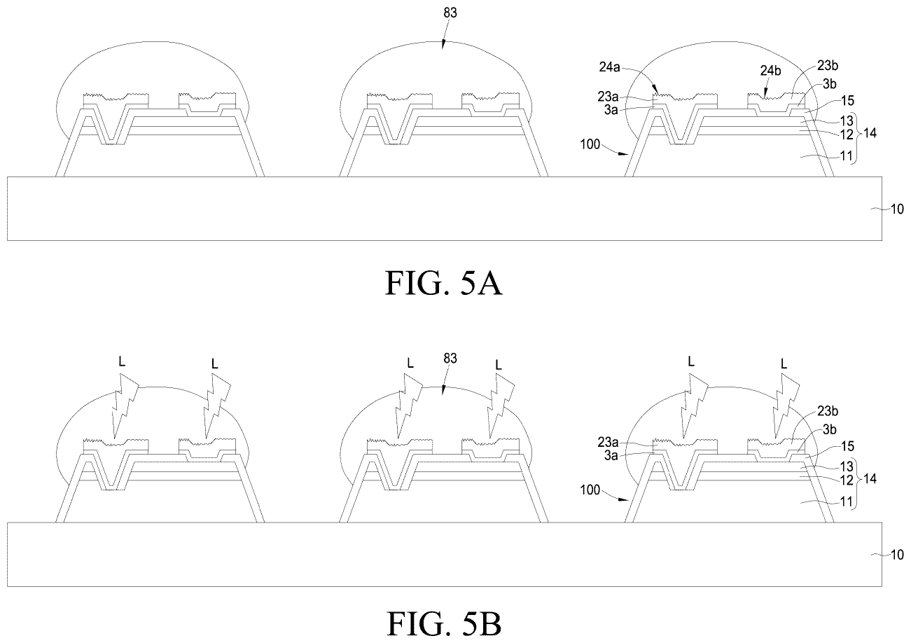

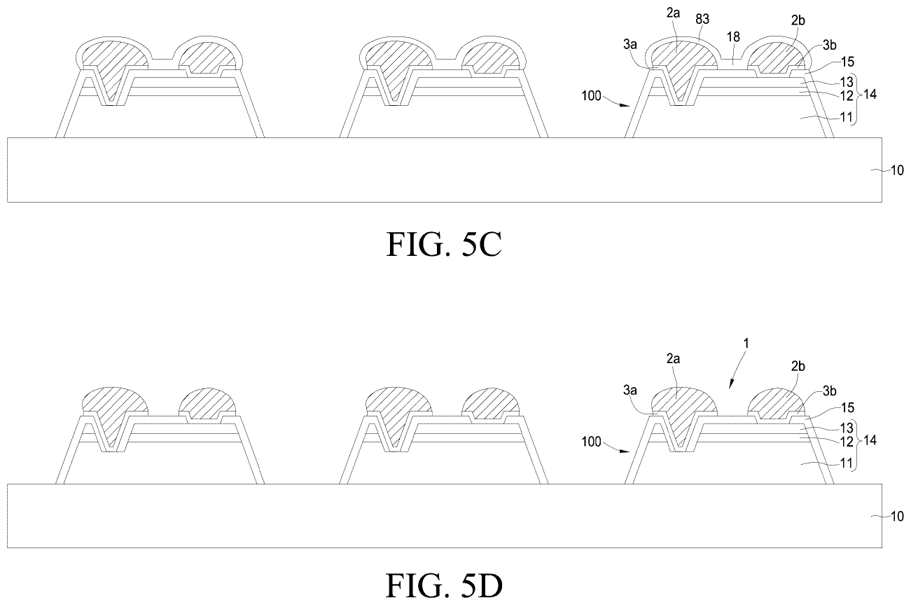

FIGS. 5A-5D illustrate a manufacturing process of a semiconductor device 1 in accordance with an embodiment of the present disclosure. As shown in FIG. 5A, a plurality of semiconductor units 100 are provided on the substrate 10. The semiconductor unit 100 includes a semiconductor stack 14, a protecting layer 15, a first electrode 3a, and a second electrode 3b. The semiconductor unit 100 is disposed on the substrate 10 such that the first electrode 3a and the second electrode 3b are away from the substrate 10. In one embodiment, the semiconductor stack 14 is a light emitting diode and includes a first type semiconductor layer 11, an active layer 12, and a second type semiconductor layer 13. The first electrode 3a and the second electrode 3b each has a recessed portion with corresponding openings. The detailed structural description can be referred to the mentioned relevant paragraphs. Firstly, a first bonding pad 23a and a second bonding pad 23b are formed on the first electrode 3a and the second electrode 3b respectively by electroplating, chemical plating, or evaporation. An upper surface 24a of the first bonding pad 23a and an upper surface 24b of the second bonding pad 23b are substantially conformal to the upper surfaces of the first electrode 3a and the second electrode 3b, that is, their outer contours are similar and have recesses and/or rough texture. A glue 83 is formed on the semiconductor unit 100, the first bonding pad 23a, and the second bonding pad 23b. In one embodiment, the glue 83 includes only resin. In another embodiment, the glue 83 includes resin and conductive particles (not shown) which have the same composition as the bonding pads 23a and/or 23b. In one embodiment, the glue 83 can be formed by printing, coating, spraying, or dispensing, wherein the printing includes aerosol jet printing or ink-jet printing. Resin includes thermosetting plastic and flux, and the thermosetting plastic can be epoxy, silicone, polymethylmethacrylate, or episulfide. When the glue 83 includes conductive particles, the melting point of the conductive particles is lower than the curing temperature of the resin. In one embodiment, the conductive particles include gold, silver, copper, or tin. In another embodiment, the conductive particles include a low melting point metal or a low liquidus melting point alloy. In one embodiment, the low melting point metal or the low liquidus melting point alloy has a melting point or a liquidus melting point below 210° C. In another embodiment, the low melting point metal or the low liquidus melting point alloy has a melting point or a liquidus melting point below 170° C. The low liquidus melting point alloy include a tin alloy, such as tin-indium alloy or tin-bismuth alloy.

As shown in FIG. 5B, a laser energy L is used to irradiate positions of the first bonding pad 23a and the second bonding pad 23b to heat the glue 83, the first bonding pad 23a, and the second bonding pad 23b. The laser energy L includes an ultraviolet (UV) laser beam, a visible laser beam, or an infrared (IR) laser beam. In one embodiment, the laser energy L is an infrared laser beam with a wavelength range of 750-2000 nm. As shown in FIG. 5C, during the heating process, the first bonding pad 23a and the second bonding pad 23b are heated and melted in the glue 83 to aggregate on the first electrode 3a and the second electrode 3b (if the resin contains conductive particles, some or all of the conductive particles can also move onto the first electrode 3a and the second electrode 3b after being heated) or partially overflow to the upper surface of the protecting layer around the electrodes (not shown), and then the first conductive bump 2a and the second conductive bump 2b with a convex arc-shaped outer contour are formed. The glue 83 can move onto the first conductive bump 2a, the second conductive bump 2b, and an area 18 between the first electrode 3a and the second electrode 3b. After the heating process is completed, the first conductive bump 2a and the second conductive bump 2b can be solidified, and the glue 83 (or resin) covering them can also be heated but is not fully solidified and is in a liquid or semi-liquid state. Next, as shown in FIG. 5D, a cleaning process is performed to remove the uncured adhesive 83 (or resin) to expose the first conductive bump 2a and the second conductive bump 2b to the external environment. The cleaning process can be carried out using a solvent, and the solvent includes N-Methylpyrrolidinone (NMP), methyl ethyl ketone (MEK), acetone (ACE), or isopropyl alcohol (ACE).

The above manufacturing process is only one type of process, but the present disclosure is not limited thereto. A process of heating and shaping the bonding pads can be applied to the semiconductor devices 2, 3 and 4 in any of the above embodiments to form the conductive bumps 2a and 2b with a convex shaped outer contour; after adjusting the structure of the semiconductor device through the above embodiments, the final conductive bumps 2a and 2b on the semiconductor device 2, 3, 4 can have a first top 21a and a second top 21b that are substantially on the same horizontal elevation. This structure allows the semiconductor device to be stably fixed on the conductive circuit of the circuit substrate or display panel through welding the conductive bumps, thereby improving the reliability of the overall structure.

Although the present disclosure is described above through specific embodiments, the inventive principles of the present disclosure can also be applied to other embodiments. In addition, in order not to obscure the spirit of the present disclosure, specific details that fall within the knowledge of a person having ordinary skill in the art will be omitted.

1. A semiconductor device, comprising:
a semiconductor stack, comprising a first type semiconductor layer and a second type semiconductor layer;
a protecting layer, located on the semiconductor stack and having n first openings and m second openings;
a first electrode, located on the n first openings and having a first outer surface, electrically connected to the first type semiconductor layer;
a second electrode, located on the m second openings and having a second outer surface, electrically connected to the second type semiconductor layer;
a first conductive bump, located on the first electrode and having a first top with a convex shaped outer contour; and
a second conductive bump, located on the second electrode and having a second top with a convex shaped outer contour;
wherein, in a cross-sectional view, the first conductive bump is connected to the first electrode through a contacting surface with a first horizontal width, the second conductive bump is connected to the second electrode through a contacting surface with a second horizontal width, and a ratio of the first horizontal width to the second horizontal width is between 0.8-1.2;
wherein the first top has a horizontal elevation substantially the same as that of the second top.

2. The semiconductor device according to claim 1, wherein, in the cross-sectional view, one of the n first openings has a first inner surface, and one of the m second openings has a second inner surface, a first included angle formed between an extending direction of the first inner surface and a horizontal line is different from a second included angle formed between an extending direction of the second inner surface and the horizontal line.

3. The semiconductor device according to claim 2, wherein, the first included angle is greater than the second included angle.

4. The semiconductor device according to claim 1, wherein, in the cross-sectional view, the first conductive bump contacts the first outer surface, the second conductive bump contacts the second outer surface, and the first outer surface and the second outer surface have different roughnesses.

5. The semiconductor device according to claim 4, wherein, the first outer surface has a greater roughness than the second outer surface.

6. The semiconductor device according to claim 4, wherein, the protecting layer covers the first electrode and the second electrode, and n=m=1.

7. The semiconductor device according to claim 1, wherein, in the cross-sectional view, the first conductive bump contacts an outer surface of the first electrode, the second conductive bump contacts an outer surface of the second electrode, and the outer surface of the first electrode and the outer surface of the second electrode have different roughnesses.

8. The semiconductor device according to claim 7, wherein, the outer surface of the first electrode has a greater roughness than the outer surface of the second electrode.

9. The semiconductor device according to claim 7, wherein, the first electrode and the second electrode cover the protecting layer, and n=m=1.

10. The semiconductor device according to claim 7, wherein, in the cross-sectional view, n is not equal to m.
